(19) United States
(12) Patent Application Publication
(10) Pub. No.: US 2026/0023332 A1
(43) Pub. Date: Jan. 22, 2026

(54) PHYSICS INFORMED ARTIFICIAL INTELLIGENCE FOR DYNAMIC SYSTEMS IN SEMICONDUCTOR MANUFACTURING

(71) Applicant: Applied Materials, Inc., Santa Clara, CA (US)

(72) Inventors: ABHINAV KUMAR, Milpitas, CA (US); SAMANEH SADIGHI, San Jose, CA (US); BRETT SCHROEDER, Portland, OR (US)

(21) Appl. No.: 18/774,817

(22) Filed: Jul. 16, 2024

(51) Int. Cl. G03F 7/00; G06F 30/33

(52) U.S. Cl. CPC G03F 7/706841; G03F 7/705; G06F 30/33

(57) ABSTRACT

Embodiments described herein relate to a method that includes implementing a feature extraction process and a feature fusion process from a data set that includes one or more chamber setting data points, where the data set is augmented by a physics attributes model that uses the one or more chamber setting data points to generate chamber attribute data of one or more processing characteristics within a chamber based on physics modeling. In an embodiment, the method further includes implementing a data segmentation process on the data set with a context specific data segmentation module to form a modified data set. In an embodiment, the method may further include training a machine learning model on the modified data set, wherein training the machine learning model includes minimizing a loss function that includes a regularized objective function that includes a term based on physics informed variables.

### BACKGROUND

### 1) Field

Embodiments of the present disclosure pertain to the field of physics informed artificial intelligence (AI) and/or machine learning (ML) for dynamic systems in semiconductor manufacturing.

### 2) Description of Related Art

The generation of semiconductor processing recipes is a tedious process that relies largely on historical data and the intuition and expertise of process engineers. Skilled process engineers are able to design and explore new process spaces that meet a desired specification through a highly iterative process that is time consuming and requires the running of multiple experiments on physical wafers. For example, existing process space exploration is limited to the process space provided in the experiments that are run on physical wafers. That is, the results provided by the experiments are largely context specific, and extrapolating beyond the boundary conditions can lead to significant errors or deviations in the desired on wafer results. Accordingly, even when there is extensive existing data for process performance, it can be expensive (e.g., with respect to tool utilization costs, employee time costs, time to market costs, etc.) to generate new processes in semiconductor manufacturing environments.

### SUMMARY

Embodiments described herein relate to a method that includes implementing a feature extraction process and a feature fusion process from a data set that includes one or more chamber setting data points, where the data set is augmented by a physics attributes model that uses the one or more chamber setting data points to generate chamber attribute data of one or more processing characteristics within a chamber based on physics modeling. In an embodiment, the method further includes implementing a data segmentation process on the data set with a context specific data segmentation module to form a modified data set. In an embodiment, the method may further include training a machine learning model on the modified data set, wherein training the machine learning model includes minimizing a loss function that includes a regularized objective function that includes a term based on physics informed variables.

Embodiments described herein relate to a method that includes accessing input data from a data set, wherein the input data includes chamber setting data. In an embodiment, the method may also include running the input data through a physics model that is a reduced order model derived from one or more multiple dimensional physics models. In an embodiment, the method may also include extracting output data from the physics model, where the output data includes one or more attributes for processing characteristics during operation of a processing chamber.

Embodiments described herein relate to a method that includes accessing a data set that includes chamber setting data, sensor data, chamber attribute data, and metrology data, where the chamber attribute data is derived from one or both of the chamber setting data and the sensor data using a reduced order physics attributes model. In an embodiment, the method may include segmenting the data set to form a modified data set. In an embodiment, the method may further include training a machine learning model on the modified data set, where training the machine learning model includes minimizing a loss function that includes a regularized objective function that includes a term based on physics informed variables.

### BRIEF DESCRIPTION OF THE DRAWINGS

FIG. 1 is a three-dimensional graph that depicts an ideal operating space that allows for the utilization of large data sets with a desired level of physics based modeling that is suitable for providing real time results, in accordance with an embodiment.

FIG. 2 is a process flow diagram that depicts a machine learning model training process and utilization of the model to make process recipe predictions, in accordance with an embodiment.

FIG. 3 is a process flow diagram of a process for augmenting a data set with chamber attribute data through the use of a physics model, in accordance with an embodiment.

FIG. 4A is a schematic of a variational auto-encoder (VAE) for use in a data segmentation process used in the training of a machine learning model, in accordance with an embodiment.

FIG. 4B is a flow diagram of the VAE for latent representation, in accordance with an embodiment.

FIG. 4C is a diagram of model training with a VAE that is augmented with a neural network model to associate metrology predictions from the latent space representation, in accordance with an embodiment.

FIG. 5 is a flow diagram of a process for training a machine learning model based with a loss function that comprises a regularized objective function and a data set that is augmented by a physics attributes model to generate chamber attribute data, in accordance with an embodiment.

FIG. 6 is a flow diagram of a process for augmenting a data set with a reduced order physics model that produces attributes for processing characteristics during operation of a processing chamber, in accordance with an embodiment.

FIG. 7 is a flow diagram of a process for training a machine learning model on a data set that comprises chamber attribute data that is physics based, in accordance with an embodiment.

FIG. 8 is a diagram of a semiconductor processing tool that is communicatively coupled to a database and a machine learning module, in accordance with an embodiment.

FIG. 9 illustrates a block diagram of an exemplary computer system of a processing tool, in accordance with an embodiment of the present disclosure.

### DETAILED DESCRIPTION

Physics informed artificial intelligence (AI) and/or machine learning (ML) for dynamic systems in semiconductor manufacturing are described herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, the existing solution for developing process recipes for semiconductor processing tools requires highly skilled process engineers, expensive physical experimentation, and long timelines. In order to expand the process space beyond the boundary conditions of existing data sets, some black box optimization functions may be used (e.g., Bayesian optimization, deep neural networks and reinforcement learnings, or support vector machines (SVM)). However, these solutions rely on sensor and/or metrology readings. That is, there is no contextual relationship of the process space to physical properties and/or conditions (e.g., plasma properties, temperatures within the volume of the chamber, electrical properties, etc.) within the processing chamber. This can lead to the generation of models that produce results that satisfy the model, but do not conform to boundaries defined by real world physics. As such, the resulting models may provide erroneous results.

Accordingly, embodiments disclosed herein may comprise machine learning (ML) models that integrate domain knowledge and governing principles of the physical system. This constrains the model prediction to be physics aware so that fundamental laws of physics are not violated and extrapolation errors are reduced or eliminated. For example, an existing data set that may comprise chamber setting data points (e.g., hardware configurations, recipe set points, chemistries, etc.) may be augmented to further include chamber attribute data (e.g., species density, radical flux, RF voltages, ion energy distribution function (IEDF), or ion angle distribution function (IADF)) through the use of a physics based model. Further, the training of the ML model may be improved through the use of a physics informed loss function that includes a regularized objective function that includes a term based on physics informed variables.

It is to be appreciated that ML techniques are capable of fitting the observed data accurately, but such techniques may possess poor generalization performance for unseen data. This can lead to significant prediction error and/or extrapolation bias. However, the addition of a physics based model allows for improved accuracy of the ML model. The added benefit of the physics based model may result in an increase in the computational load of the model due to the need to solve high fidelity numerical equations. The computational load may render some applications unsuitable for process development in time critical environments, such as in the semiconductor manufacturing industry. In order to reduce the computational load, embodiments may include the generation of a reduced order physics model. As such, real time (or near real time) generation of physics informed data can be added to the data set.

Embodiments disclosed herein allow for the generation of a real time (or near real time) physics aware ML model of a desired process space. Such a ML model is enabled through several aspects of embodiments disclosed herein. One enabling aspect is the transformation of large data sets comprising data of historical experiments to smaller application specific (or targeted experimentation intent) structured subsets of data through the use of smart data reduction techniques. Another enabling aspect is the generation and inclusion of physics aware data which can be calculated in real time (or near real time) from experimental setup. The reduced computational load to generate the physics aware data quickly is enabled through the use of a reduced order model of governing physical systems which describe one or more material properties, geometric characteristics, initial conditions, boundary settings, system configurations, or the like. Another enabling aspect is the use of an improved loss function for ML model training. In an embodiment, the improved loss function may comprise a regularization parameter in the loss function to guide the prediction to be physics aware.

Accordingly, embodiments disclosed herein allow for quick process discovery, which leads to improved execution time for the process discovery. Reduced learning cycles can allow for convergence to a desired specification or process recipe faster and more efficiently (e.g., by reducing the number of physical experiments that are needed to validate the solution). This can lead to a faster go-to-market timeline and product releases which allows users to develop and integrate new processes into their devices faster.

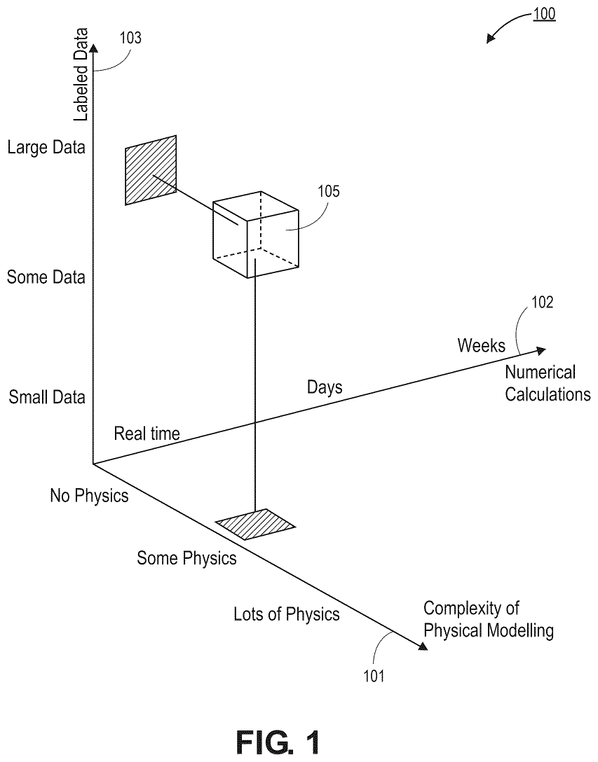

Referring now to FIG. 1, a three-dimensional graph 100 that depicts an ideal operating space 105 generated by a machine learning (ML) model using a large data sets with a desired level of physics based modeling is shown, in accordance with an embodiment. The axis 101 illustrates a desired level of physics modeling complexity. For example, at the origin there is no physics modeling incorporated into the ML model, and the amount of physics incorporated into the ML model increases along axis 101. The axis 102 represents the time required to accomplish numerical calculations. For example, near the origin the numerical calculations may be accomplished in real time. As used herein, “real time” or “near real time” may refer to a period of time that is approximately 1 minute or less, five minutes or less, 30 minutes or less, 1 hour or less, 10 hours or less, or 1 day or less. In an embodiment, the axis 103 represents the size of a data set used to train the ML model. For example, at the origin the data set may have a relatively small amount of data, and the amount of data in the data set increases along the axis 103.

It is to be appreciated that increasing the size of the data set and increasing the amount of physics incorporated into the ML model will tend to increase the accuracy and the reliability of the ML model. However, blindly increasing both the size of the data set and/or increasing the amount of physics incorporated into the ML model will generally increase the period of time required to train the ML model. Accordingly, embodiments disclosed herein provide various aspects to more efficiently use the data and/or process the physics equations. For example, the physics model (or models) of the ML model may be simplified into a reduced order physics model, and/or the data set may be segmented with a context specific data segmentation process. The context specific data segmentation process may include clustering the data from the data set so that parameters (e.g., device, chamber, hardware, chemistry, material composition, or combinations thereof) that are similar to those being investigated by the ML model are selected for training in order to reduce the size of the data set for a particular training operation.

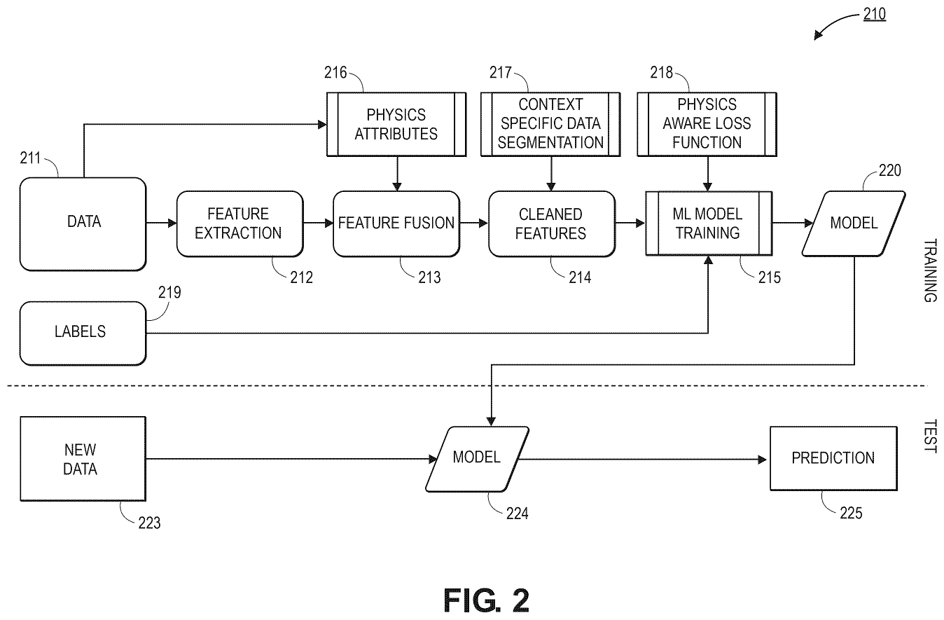

Referring now to FIG. 2, a flow diagram of a process 210 for training a ML model 220 and using the ML model 220 for generating a prediction 225 for a new process space is shown in accordance with an embodiment. In an embodiment, the process 210 may begin with accessing a data set 211. The data set 211 may comprise historical data of a plurality of process operations in one or more chambers (e.g., tens of process operations, hundreds of process operations, thousands of process operations, tens of thousands of process operations, hundreds of thousands of process operations, or more). In an embodiment, the data in the data set 211 may include data relating to the plurality of process operations that includes one or more recipe set points, one or more hardware configurations, one or more chemistry input data points (e.g., processing gas chemistries, layer compositions on a wafer, etc.), metrology results (e.g., film thicknesses, film thickness uniformity, film resistivities, etc.), sensor readings, or the like. In an embodiment, the process may proceed with a feature extraction

process 212. The feature extraction process may be similar to any suitable feature extraction process for data sets typical of ML training processes. For example, the feature extraction process may include a process for transforming raw data in the data set into numerical features that are compatible with algorithms used in the ML model. For example, this process may be used to reduce complexity of the data set, while retaining as much relevant information as possible. In some instances the feature extraction process 212 involves encoding the data into a feature vector by identifying which features are most predictive of a desired outcome in order to eliminate noise in the data set.

In an embodiment, the process may proceed with a feature fusion process 213. The feature fusion process 213 may be similar to any suitable feature fusion process for data sets typical of ML training. For example, the feature fusion process 213 may include a process for combining features from different sources to improve the ML model's capabilities. In a particular embodiment, feature fusion process 213 may incorporate data from the feature extraction process 212 and augmented data from a physics attributes model 216. The physics attributes model 216 may be a physics based model that takes the data from the data set 211 and outputs chamber attribute data of one or more processing characteristics within a chamber based on a set of physics based equations. In an embodiment, the one or more processing characteristics may comprise processing conditions within a chamber during processing that are otherwise unknown such as, for example, species density, radical flux, RF voltages, ion energy distribution function (IEDF), or ion angle distribution function (IADF).

The physics attributes model 216 may incorporate governing physical systems which describe one or more of material properties, geometric characteristics, initial conditions, boundary settings, system configurations, or the like. As can be appreciated, the incorporation of such a multiple dimensional physics model may require a large number of computations in order to fully resolve a solution that provides values for the one or more processing characteristics. Accordingly, embodiments disclosed herein may reduce the multiple dimension physics model to a reduced order physics model in order to reduce the computational complexity of the physics attributes model 216. A more detailed explanation of the physics attributes model 216 is provided in greater detail below.

In an embodiment, the process 210 may continue with a data cleaning process 214. In an embodiment, the data cleaning process 214 may be similar to any data cleaning process typically used in ML models. For example, data cleaning may include removing correcting errors, outliers, missing values, inconsistencies, and/or the like. In an embodiment, the data cleaning process may also include a context specific data segmentation process 217. The context specific data segmentation process 217 may include a process for grouping and/or sorting data from the feature fusion process 213 into context specific groups or subsets. This process allows for the ML model to isolate small, context specific, sections within the larger set of data in order to provide better resolution, improved performance, and/or improved efficiency when training the ML model in a specific process space. For example, the context specific data segmentation process 217 may provide clusters that relate to one or more of a particular type of chamber, a particular type of processing recipe (e.g., etching, deposition, plasma treatment, etc.), a particular set of chemistries, or the like. In an embodiment, the context specific data segmentation process 217 may include the use of a variational auto-encoder (VAE). A more detailed explanation of the context specific data segmentation process 217 is described in greater detail herein.

In an embodiment, the process 210 may continue with a ML model training process 215. In an embodiment, the ML model training process may include a training process that is similar to other ML training processes. For example, the ML model training process 215 may include the minimization of a loss function. However, embodiments disclosed herein may further include incorporating a physics aware loss function 218 into the ML model training process 215. For example, the physics aware loss function 218 may include a regularized objective function that includes a term based on physics informed variables. This allows for the weight attributed to the physics aware data to be modified in order to improve the accuracy of the ML model 220. The ML model training process 215 may also include labels 219 (raw or structured) that allows for supervised learning. For example, the labels 219 may include metrology data in some instances. Though, in other embodiments, the ML model training process 215 may be unsupervised.

The training may result in the generation of the ML model 220 that can be used for subsequent investigation in order to make predictions 225 in a testing regime. For example, the predictions 225 may include a process recipe prediction that includes chamber configurations, process gas flow rates, temperatures, pressures, voltages, etc. In an embodiment, an ML model 224 under investigation may be fed new data 223 in order to refine the prediction 225. The new data 223 may be sourced from physical experiments targeted to the new process recipe. Though, due to the strength of the ML model 224, the number of physical experiments are significantly reduced. Embodiments may also include a testing regime that does not use any new data 223.

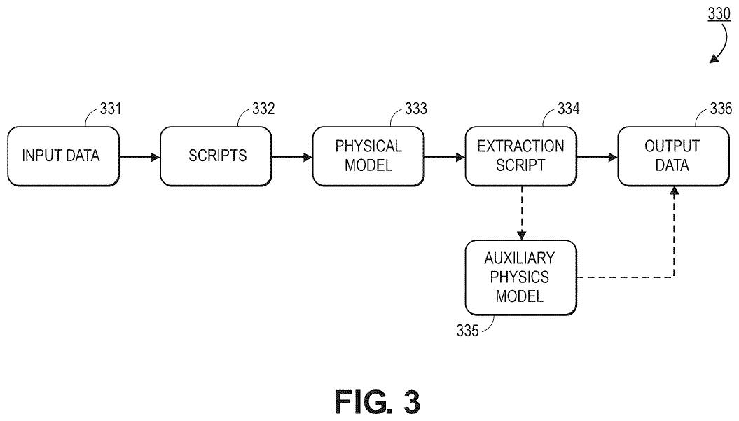

Referring now to FIG. 3, a flow diagram of a process 330 for implementing a physics attributes model is shown, in accordance with an embodiment. In an embodiment, the process 330 may begin with input data 331. The input data 331 may be from a large data set, such as data set 211 described in greater detail herein. For example, the input data 331 may comprise chamber information, recipe set points, chemistries, and/or the like. In an embodiment, the process 330 may continue with the execution of one or more scripts 332. The one or more scripts 332 may be used to create physics model input files. These physics model input files may describe conditions such as, for example, gas ratios, chemical reactions that take place in the chamber, chamber setup configurations, and/or the like. In an embodiment, the physics model input files may represent a multiple dimension physics based system that accurately represents the physics based relationships within the chamber.

In an embodiment, the process 330 may continue with the generation of a reduced order physics model 333. The reduced order physics model 333 may be used to convert the computationally complex multiple dimensional physics based system into a simpler model that is less computationally complex. As such, the reduced order physics model 333 can run at significantly faster speeds in order to allow for real time or near real time augmentation of the data set to provide physics based data into the data set. The reduced order physics model 333 may be generated through any suitable process, such as a model-based reduced order model generation method and/or a data-driven generation method.

In an embodiment, the process 330 may proceed with the use of one or more extraction scripts 334 that allow for the generation of physics based data from the reduced order physics model 333. For example, the physics based data may comprise one or more of species densities, radical fluxes, RF voltages, and/or the like. In some embodiments, the physics based data may run through an auxiliary physics model 335. The auxiliary physics model 335 may also be a reduced order physics model that is used to generate additional physics based data based on the physics based data obtained by the extractions scripts 334. For example, additional physics based data may include values such as, for example, IEDF, IADF, or the like. In an embodiment, the process 330 may proceed with the collection and/or reporting of output data 336. The output data 336 may be provided for use in the feature fusion process 213 described in greater detail herein. In an embodiment, the output data 336 may be considered as being independent samples from an unchanging underlying distribution. In other words, the output data is assumed to consist of distinct, independent measurements from the same (unchanging) system. Such data may sometimes be referred to as independently and identically distributed (iid).

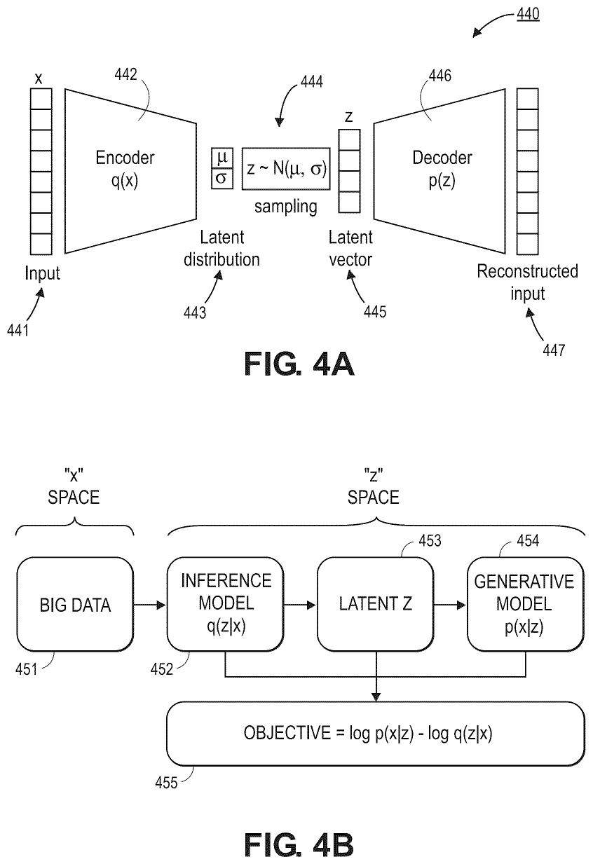

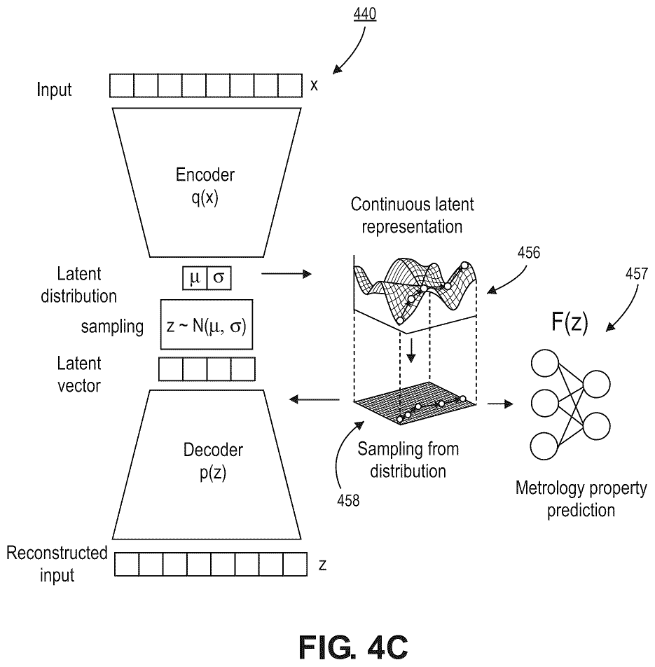

Referring now to FIG. 4A, a diagram of a VAE for use in a context specific data segmentation process used in the training of machine learning model, in accordance with an embodiment. In an embodiment, the data segmentation process may be used to group data into specific application and/or experimentation clusters. For example, the clustering may include chamber type clustering, process type clustering (e.g., pattern type such as contact holes, line space structures, or any other logic device pattern, or pattern structure information such as pitch or aspect ratio). Clustering may also include hardware configurations, chemistry types, layer compositions on the wafer, stack compositions on the wafer, layer thicknesses, process parameter (which may include sensor recordings), metrology results (such as uniformity measures, resistivity measures, etc.), or any combination thereof.

In an embodiment, FIG. 4A depicts a VAE 440 for the context specific data segmentation process. In an embodiment, the encoder 442 of the VAE 440 outputs parameters of a pre-defined distribution in the latent distribution 443 for every input 441. The VAE 440 then imposes a constraint 444 on the latent distribution 443 that forces a normalized distribution for the latent vectors 445. In an embodiment, the latent vectors 445 in the VAE 440 comprise a mean and a standard deviation for each hidden variable in the middle layer.

In an embodiment, the VAE 440 generalizes the auto-encoder and adds stochasticity to the VAE 440. When the stochasticity is combined with a penalty term, all areas of the latent space are encouraged to correspond to a valid decoding by the decoder 446. The intuition is that adding noise to the encoded molecules forces the decoder 446 to learn how to decode a wider variety of latent pints and find more robust representations. In addition, since two different molecules can have their encodings stochastically brought close in the latent space, but still need to decode to different molecular graphs in the reconstituted input 447, this process encourages the encodings to spread out over the entire latent space in order to avoid overlap.

Referring now to FIG. 4B, a process flow diagram of the VAE 440 for latent representation is shown, in accordance with an embodiment. As shown, the process may begin with accessing a big data set 451. The data set 451 may be similar to data set 211 or the augmented data set (with physics informed data) described in greater detail herein. The data set 451 may be part of the x-space of the VAE 440. In an embodiment, an inference model 452 is used to generate a latent z space 453 in the z-space. A generative model 454 may be used to process the latent z space 453. Outputs from the z-space may be used to produce an objective 455.

In an embodiment, the context specific data segmentation may further rely on one or more other techniques to improve the clustering process. For example, unsupervised deep embedded clustering (DEC) may be used. DEC may include one or more of deep representation learning, soft clustering, joint optimization, and/or iterative refinement may also be used. With respect to deep representation learning, a deep neural network (typically a variational auto-encoder or an auto-encoder) is used to learn a compact and informative representation of the input data. This network transforms the input data into a lower-dimensional space where each dimension represents certain features or characteristics of the data. With respect to soft clustering, after the embedded representations are obtained, the DEC applies a clustering algorithm, often K-means, to cluster the data points in the lower-dimensional space. However, instead of assigning data points to hard clusters, DEC uses a soft clustering approach. This means that each data point is assigned a probability distribution over the clusters, indicating how likely it belongs to each cluster. With respect to joint optimization, the objective of DEC is to jointly optimize the neural network's parameters and the cluster assignments in such a way that the embedded representations are both useful for clustering and informative for the data distribution. This is achieved through an iterative process where the network's parameters and the cluster assignments are updated alternately to minimize a combined loss function. With respect to iterative refinement, during each iteration, the network's weights are updated to improve the quality of the learned representations, which in turn affects the clustering assignments. The clustering assignments are updated based on the distances between data points and cluster centers in the embedded space.

Referring now to FIG. 4C, a joint training model with an additional objective to correspond the process space encoded in the continuous representation of the VAE 440 to target metrology attributes or properties that are desired to be optimized is shown, in accordance with an embodiment. In an embodiment, a neural network model 457 is added to the VAE 440 that predicts the properties from the latent space representation 456. This VAE 440 is then trained jointly on the reconstruction task and a property from the latent vector of the encoded process space. To propose new recipe parameters, chemistries, hardware configurations, or the like, the process may start from the latent vector of an encoded space then move in the direction of most likely to improve the desired attribute as indicated by the sampling from the distribution 458.

In an embodiment, the ML training process may also comprise a minimizing a loss function that comprises a regularized objective function that includes a term based on physics informed variables. Generally, the objective function may be defined as the loss function added to the regularization. A more detailed description is shown in Equation 1.

$$J ( w , b ) = \frac{1}{2 m} {\sum }_{i = 1}^{m} {( f ( {x}^{i} ) - {y}^{i} )}^{2} + \frac{λ}{2 m} {\sum }_{j = 1}^{n} {w}_{j}^{2} + μ l ( f ( x ) , s ) \qquad Equation 1$$

For a given a set of inputs xⁱ (i.e., recipe parameters), and the corresponding targets, yⁱ (i.e., metrology), Equation 1 defines the set of variables s to which the dependence needs to be emphasized. In an embodiment, s represents the physics informed variables, and J is the objective function which needs to be minimized. In an embodiment,/measures statistical dependence between the model f(x) and physics attributes s can include the Hilbert-Schmidt Independence Criterion (HSIC). In an embodiment, λ is the regularization parameter from [0, ∞], μ is to regularize the dependence of objective function to put more/less weightage on physics attribute from [−∞, +∞].

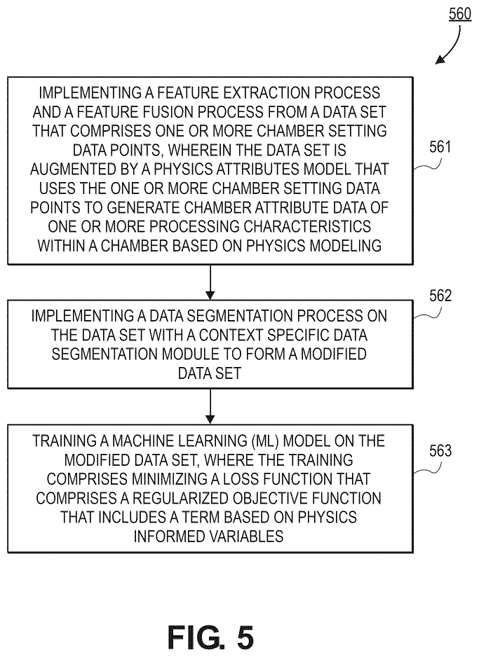

Referring now to FIG. 5, a flow diagram of a process 560 for training a ML model is shown, in accordance with an embodiment. In an embodiment, the process may begin with operation 561, which comprises implementing a feature extraction process and a feature fusion process from a data set that comprises one or more chamber setting data points. In an embodiment, the data set is augmented by a physics attributes model that uses the one or more chamber setting data points to generate chamber attribute data of one or more processing characteristics within a chamber based on physics modeling. In an embodiment, the data further comprises sensor recordings from within the chamber, and/or one or more chamber setting data points comprise one or more recipe set points and/or one or more hardware configurations or any other types of data described herein with respect to data sets described in greater detail herein.

In an embodiment, the physics attributes model is a reduced-order physics model based on one or more multiple dimension physics models that include physics based relationships that allow for the generation of the chamber attribute data. For example, chamber attribute data comprises one or more of species density, radical flux, RF voltages, IEDF, or IADF. Though, it is to be appreciated that any type of chamber data generated by the physics models described in greater detail herein may also be included in the chamber attribute data.

In an embodiment, the process 560 may continue with operation 562, which comprises implementing a data segmentation process on the data set with a context specific data segmentation module to form a modified data set. the data segmentation process comprises the use of a VAE. In an embodiment, the data segmentation process may also comprise the use of one or more of deep representation learning, soft clustering, joint optimization, or iterative refinement.

In an embodiment, the process 560 may further continue with operation 563, which comprises training a machine learning model on the modified data set, where the training comprises minimizing a loss function that comprises a regularized objective function that includes a term based on physics informed variables. In an embodiment, the regularized objective function is configured to change the weight attributed to the physics informed variables. In an embodiment, training the ML model may further comprise incorporating a neural network model to the VAE to correlate a process space encoded in the continuous representation of the VAE to one or more target metrology attributes. In some instances, the training may comprise training both networks with a shared objective.

In some embodiments, the ML model is used to design a process space for semiconductor processing a processing tool. Additionally, the ML model is capable of generating predictions in the process is space in real time or in near real time. For example, the ML model can generate the process space in one day or less. In some embodiments, the training of the ML model is supervised or unsupervised.

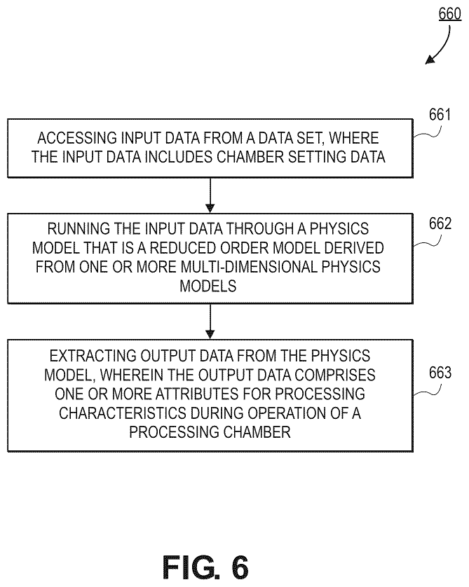

Referring now to FIG. 6, a flow diagram of a process 660 for augmenting a data set with extracting physics based output data from a data set is shown, in accordance with an embodiment. In an embodiment, the process 660 may begin with operation 661, which comprises accessing input data from a data set. In an embodiment, the input data includes chamber setting data or any other type of data included in any data set (such as data set 211) described in greater detail herein. For example, the input data may comprise one or more of recipe set points, chemistry, hardware configurations, or sensor recordings.

In an embodiment, the process 660 may continue with operation 662, which comprises running the input data through a physics model that is a reduced order model derived from one or more multiple dimensional physics models. For example, the one or more multiple dimensional physics models describe one or more of chemical interactions, plasma interactions, or electrical interactions produced by one or more chamber configurations represented by the chamber setting data.

In an embodiment, the process 660 may continue with operation 663, which comprises extracting output data from the physics model. In an embodiment, the output data comprises one or more attributes for processing characteristics during operation of a processing chamber. For example, the one or more attributes may include one or more of species density, radical flux, RF voltages, IEDF, IADF, or any other type physics based data described in greater detail herein. In some embodiments, the processing chamber is a semiconductor processing chamber.

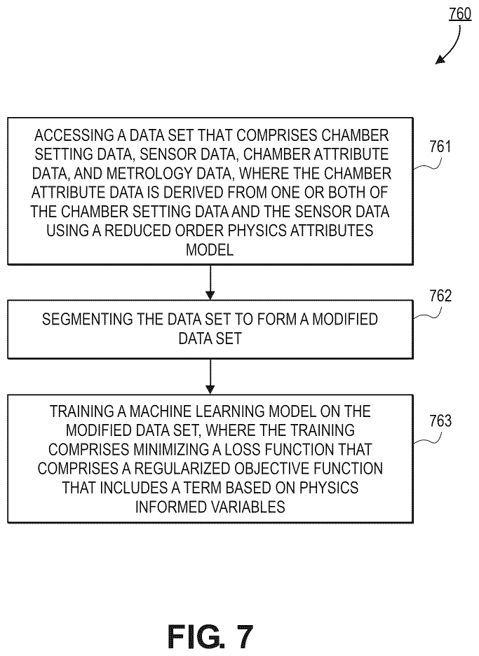

Referring now to FIG. 7, a flow diagram of a process 760 for training a ML model is shown, in accordance with an embodiment. In an embodiment, the process 760 may begin with operation 761, which comprises accessing a data set that comprises chamber setting data, sensor data, chamber attribute data, and metrology data. In an embodiment, the chamber attribute data is derived from one or both of the chamber setting data and the sensor data using a reduced order physics attributes model. The data set may comprise any other type of data described in data sets (such as data set 211) described in greater detail herein. For example, the chamber setting data comprises one or more of recipe set points, hardware configurations, or processing chemistries. In an embodiment, the chamber attribute data may include one or more of species density, radical flux, RF voltages, IEDF, IADF, or any other type of physics based data described in greater detail herein.

In an embodiment, the process 760 may continue with operation 762, which comprises data segmentation of the data set to form a modified data set. In an embodiment, the data segmentation may be a context specific data segmentation, such as any of the context specific data segmentations describer in greater detail herein. For example, a VAE may be used in some embodiments.

In an embodiment, the process 760 may continue with operation 763, which comprises training a machine learning model on the modified data set. In an embodiment, the training comprises minimizing a loss function that comprises a regularized objective function that includes a term based on physics informed variables.

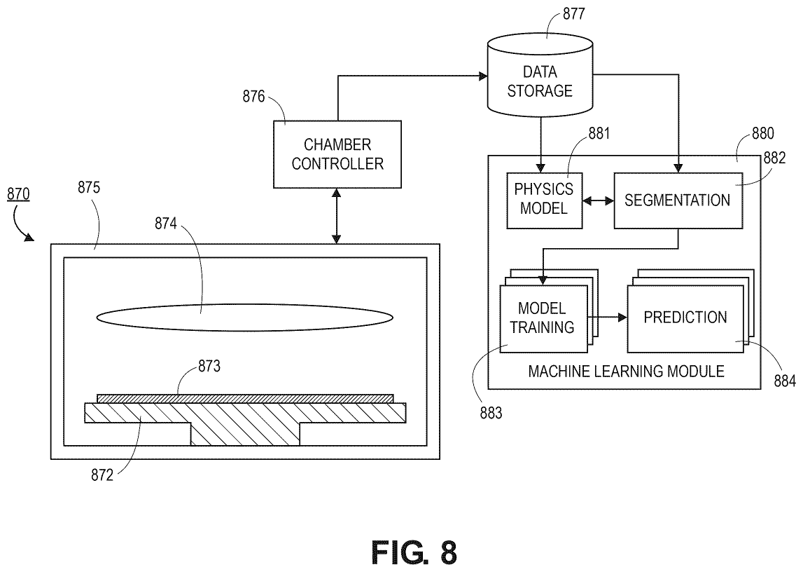

Referring now to FIG. 8, a schematic illustrations of a system that includes a processing tool 870 that is communicatively coupled to a machine learning module 880 is shown, in accordance with an embodiment. In an embodiment, the processing tool 870 may comprise any semiconductor processing tool within a semiconductor fabrication facility. For example, the processing tool 870 may comprise a deposition chamber, an etching chamber, a plasma treatment chamber, a rapid thermal processing chamber, or the like. In an embodiment, the processing tool 870 may comprise a chamber 875. The chamber 875 may be suitable for supporting a vacuum environment that is capable of forming a plasma 874 in some embodiments. A substrate 873 (e.g., a semiconductor wafer, a glass panel, an organic panel, or the like) may be supported on a pedestal 872. Additional features of the processing tool 870 (e.g., electrodes, exhausts, gas lines, ports, sensors, etc.) are omitted for simplicity.

In an embodiment, the processing tool 870 may be controlled by a chamber controller 876. The chamber controller 876 may have process recipes or other parameters saved in a data storage. The chamber controller 876 may direct the processing tool 870 to run one or more different process recipes on the substrate 873. In an embodiment, the chamber controller 876 may be communicatively coupled to a database 877. The chamber controller 876 may deliver processing data (e.g., recipe set points, chamber hardware configurations, chemistries, sensor recordings, etc.) to the database 877. The database 877 may also receive metrology data from a metrology tool (not shown) used to measure the substrate 873 after processing so that metrology data for the substrate 873 can be associated with the processing data of the substrate 873.

In an embodiment, the database 877 may be communicatively coupled to the ML module 880. The ML module 880 may be a module that is capable of implementing any of the ML training processes used to train and/or test ML models described in greater detail herein. For example, the ML module 880 may include a physics model 881 (e.g., a reduced order physics model used to generate physics based data from one or both of the processing data or the metrology data). The ML module 880 may also comprise a data segmentation module 882, such as one that comprises a VAE to enable context specific data segmentation similar to any of the embodiments described in greater detail herein. In an embodiment, model training modules 883 may be used to train various ML models. The model training modules 883 may include a system for minimizing a loss function that comprises a regularized objective function that includes a term based on physics informed variables. In an embodiment, the model training modules 883 may be used to generate the ML models that are then used to generate predictions 884 (e.g., new process spaces, process recipes, or the like).

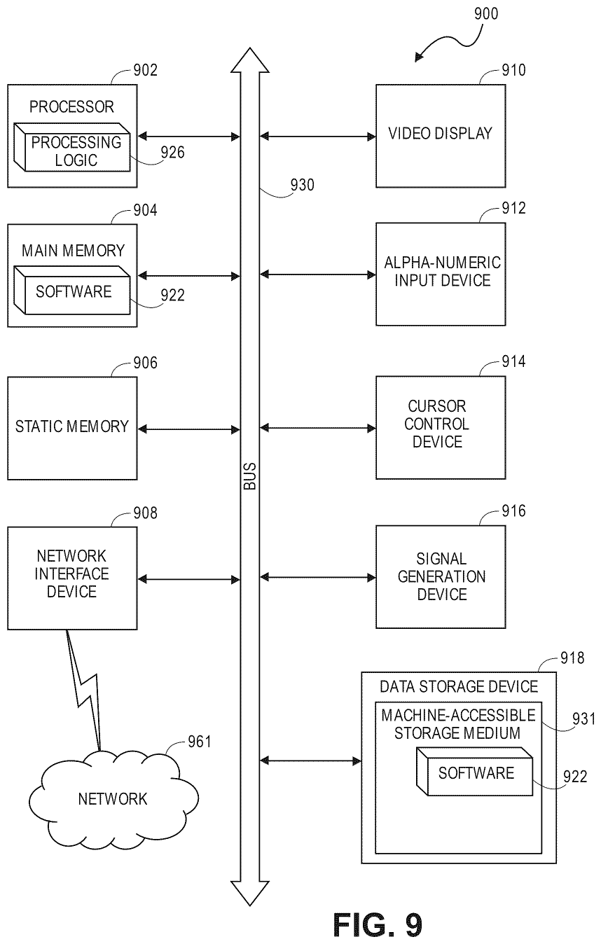

Referring now to FIG. 9, a block diagram of an exemplary computer system 900 of a processing tool is illustrated in accordance with an embodiment. In an embodiment, computer system 900 is coupled to and controls processing in an ML module that is used to develop and train ML models in real time based on physics informed data.

As used herein, specific reference is made to machine learning (ML) applications. It is to be appreciated that ML may be considered a subset of artificial intelligence (AI) in some interpretations. Further, it is to be appreciated that systems, processes, and/or the like that make reference to use in conjunction with ML may also be used (or adapted for use) in conjunction with any suitable AI technology, as those skilled in the art will appreciate.

Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using microwave coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems that include an ML module that is used to develop and train ML models in real time based on physics informed data.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. A method, comprising:
implementing a feature extraction process and a feature fusion process from a data set that comprises one or more chamber setting data points, wherein the data set is augmented by a physics attributes model that uses the one or more chamber setting data points to generate chamber attribute data of one or more processing characteristics within a chamber based on physics modeling;
implementing a data segmentation process on the data set with a context specific data segmentation module to form a modified data set; and
training a machine learning model on the modified data set, wherein training the machine learning model comprises minimizing a loss function that comprises a regularized objective function that includes a term based on physics informed variables.

2. The method of claim 1, wherein the data set further comprises sensor recordings from within the chamber.

3. The method of claim 1, wherein the one or more chamber setting data points comprise one or more recipe set points and/or one or more hardware configurations.

4. The method of claim 1, wherein the physics attributes model is a reduced-order physics model based on one or more multiple dimension physics models that include physics based relationships that allow for the generation of the chamber attribute data.

5. The method of claim 4, wherein the chamber attribute data comprises one or more of species density, radical flux, RF voltages, ion energy distribution function (IEDF), or ion angle distribution function (IADF).

6. The method of claim 1, wherein the data segmentation process comprises the use of a variational auto-encoder (VAE).

7. The method of claim 1, wherein training the machine learning model further comprises incorporating a neural network model to the VAE to correlate a process space encoded in a continuous representation of the VAE to one or more target metrology attributes.

8. The method of claim 1, wherein the data segmentation process comprises one or more of deep representation learning, soft clustering, joint optimization, or iterative refinement.

9. The method of claim 1, wherein the regularized objective function is configured to change a weight attributed to the physics informed variables.

10. The method of claim 1, wherein the machine learning model is used to design a process space for semiconductor processing a processing tool.

11. The method of claim 10, wherein the machine learning model can generate the process space in one day or less.

12. The method of claim 1, wherein training the machine learning model is supervised or unsupervised.

13. A method, comprising:
accessing input data from a data set, wherein the input data includes chamber setting data;
running the input data through a physics model that is a reduced order model derived from one or more multiple dimensional physics models; and
extracting output data from the physics model, wherein the output data comprises one or more attributes for processing characteristics during operation of a processing chamber.

14. The method of claim 13, wherein the one or more multiple dimensional physics models describe one or more of chemical interactions, plasma interactions, or electrical interactions produced by one or more chamber configurations represented by the chamber setting data.

15. The method of claim 13, wherein the chamber setting data comprises one or more of recipe set points, chemistry, hardware configurations, or sensor recordings.

16. The method of claim 13, wherein the one or more attributes comprises one or more of species density, radical flux, RF voltages, ion energy distribution function (IEDF), or ion angle distribution function (IADF).

17. The method of claim 13, wherein the processing chamber is a semiconductor processing chamber.

18. A method comprising:
accessing a data set that comprises chamber setting data, sensor data, chamber attribute data, and metrology data, wherein the chamber attribute data is derived from one or both of the chamber setting data and the sensor data using a reduced order physics attributes model;
segmenting the data set to form a modified data set; and
training a machine learning model on the modified data set, wherein training the machine learning model comprises minimizing a loss function that comprises a regularized objective function that includes a term based on physics informed variables.

19. The method of claim 18, wherein the chamber setting data comprises one or more of recipe set points, hardware configurations, or processing chemistries, and wherein the chamber attribute data comprises one or more of species density, radical flux, RF voltages, ion energy distribution function (IEDF), or ion angle distribution function (IADF).

20. The method of claim 18, wherein segmenting the data set comprises the use of a variational auto-encoder (VAE).
